(19) United States
(12) Patent Application Publication
(10) Pub. No.: US 2019/0122873 A1
(43) Pub. Date: Apr. 25, 2019

(54) Ion Source Device, Sputtering Apparatus and Method

(71) Applicant: Vitalink Industry (Shenzhen) Co., Ltd., Shenzhen (CN)

(72) Inventors: Yan Fang ZHANG, Shenzhen (CN); Tao XUE, Shenzhen (CN); Hei Ping CHUNG, Shenzhen (CN); Sing Kai CHONG, Wan Chai (HK)

(73) Assignee: Vitalink Industry (Shenzhen) Co., Ltd.

(21) Appl. No.: 15/789,785

(22) Filed: Oct. 20, 2017

(51) Int. Cl. H01J 37/34; C23C 14/00; C23C 14/06; C23C 14/35; C23C 14/50

(52) U.S. Cl. CPC H01J 37/3417; C23C 14/0057; C23C 14/0036; C23C 14/0611; H01J 37/3426; C23C 14/352; C23C 14/505; H01J 37/3405; H01J 37/3423; C23C 14/0641

(57) ABSTRACT

An ion source device (10) includes a first magnetron cathode (14a) and a second magnetron cathode (14b, 208a, 208b), each having a respective central longitudinal axis (Mₐ, M_{b}) and an ion source unit (16) that emits ions to pass through a space between the cathodes, a surface (18) of the ion source unit facing generally the cathodes, the central longitudinal axes being spaced apart from each other by a distance A, a shortest line (D) joining a surface of the cathodes is of a distance B, a centre of the ion source unit lying on a line (E) perpendicular to and bisecting the shortest line, the shortest distance between the surface of the ion source unit and the shortest line is C, with B>10 mm and C<4 A.

### BACKGROUND OF THE INVENTION

In coating by magnetron sputtering, a substrate to be coated is placed in a chamber (called a “vacuum chamber” or “treatment chamber”) set at a relatively low pressure, into which argon (Ar) gas is introduced as the working gas. A negative electric voltage of several hundred volts is applied to a number of magnetron cathode targets in the vacuum chamber. Under the negative voltage, argon atoms are ionized into positively charged argon ions and electrons, and the electrons thus generated further ionize other argon atoms to generate more argon ions and electrons, and so on, until an avalanche effect occurs whereby a plasma of continuous glow discharge is formed in front of the magnetron sputtering targets. Under the influence of the electric field, the argon ions collide onto the magnetron cathode targets and particles of the targets are sputtered out and deposited on the substrate to be coated to form a coating. If such other gases as nitrogen (N₂), oxygen (O₂) and acetylene (C₂H₂) are introduced during the sputtering process, these reactive gases will also be ionized and chemically react with the sputtered particles of the targets, so as to form a coating of a chemical compound on the surface of the substrate to be coated. Coating by a magnetron sputtering technique has been used in surface treatment and coating of materials.

Various tests have shown that if only the magnetron sputtering technique is used in generating plasma fields, the ionization of argon gas or reactive gases is not sufficient, which would reduce the sputtering efficiency, resulting in slow growth of the coating thickness. At the same time, the materials sputtered out from the targets are also not completely ionized, resulting in insufficient chemical reaction.

It is thus an object of the present invention to provide an ion source device, a sputtering apparatus including such a device and a sputtering method in which the aforesaid shortcomings are mitigated or at least to provide a useful alternative to the trade and public.

### SUMMARY OF THE INVENTION

According to a first aspect of the present invention, there is provided an ion source device including at least a first magnetron cathode and a second magnetron cathode, each having a respective central longitudinal axis, and an ion source unit with a surface facing generally said first magnetron cathode and said second magnetron cathode, wherein said ion source unit is adapted to emit ions to pass through a space between said first magnetron cathode and said second magnetron cathode.

According to a second aspect of the present invention, there is provided a sputtering apparatus including at least an ion source device including at least a first magnetron cathode and a second magnetron cathode, each having a respective central longitudinal axis, and an ion source unit with a surface facing generally said first magnetron cathode and said second magnetron cathode, wherein said ion source unit is adapted to emit ions to pass through a space between said first magnetron cathode and said second magnetron cathode

According to a third aspect of the present invention, there is provided a sputtering method, including (a) providing a treatment chamber with at least one ion source device including at least a first magnetron cathode and a second magnetron cathode, each having a respective central longitudinal axis, and an ion source unit with a surface facing generally said first magnetron cathode and said second magnetron cathode, wherein said ion source unit is adapted to emit ions to pass through a space between said first magnetron cathode and said second magnetron cathode, (b) placing at least one substrate to be treated in said treatment chamber, (c) applying an electric voltage to said first magnetron cathode and said second magnetron cathode to form a plasma field between said substrate and said first magnetron cathode and said second magnetron cathode, (d) rotating said substrate relative to said ion source device, (e) supplying at least one gas to said ion source unit, and (0 energizing said ion source unit to ionize said at least one gas, to emit ions of said at least one gas, and to cause said ions of said at least one gas to pass through a space between said first magnetron cathode and said second magnetron cathode to reach said plasma field.

### BRIEF DESCRIPTION OF THE DRAWINGS

Embodiments of the present invention will now be described, by way of examples only, with reference to the accompanying drawings, in which:

FIG. 1 is a schematic view of a linear ion source device according to an embodiment of the present invention and a substrate to be treated;

FIG. 2 is a schematic view of a linear ion source assisted sputtering apparatus according to a further embodiment of the present invention;

FIG. 3 is an enlarged view of the part marked P in FIG. 2;

FIG. 4 is a schematic view of a linear ion source assisted sputtering apparatus according to another embodiment of the present invention; and

FIG. 5 is an enlarged view of the part marked Q in FIG. 4.

### DETAILED DESCRIPTION OF THE EMBODIMENTS

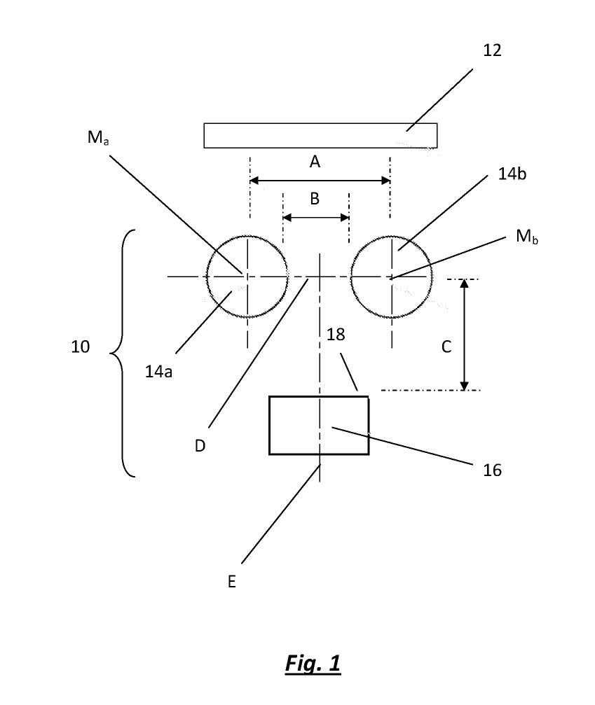

FIG. 1 shows a schematic view of a linear ion source device according to an embodiment of the present invention, generally designated as 10, and a substrate 12 to be treated, e.g. to be coated. The substrate 12 may be an article (such as a casing for such products as watches, mobile phones and tablet computers) made of a metal or metal alloy (such as stainless steel).

The linear ion source device 10 includes two spaced-apart cylindrical magnetron cathodes 14a, 14b, each having a respective central longitudinal axis Mₐ, M_{b}. The distance between the central longitudinal axis Mₐ of the cylindrical magnetron cathode 14a and the central longitudinal axis M_{b} of the cylindrical magnetron cathode 14b is A. The distance of a shortest line D joining the outer surface of the magnetron cathode 14a and the outer surface of the magnetron cathode 14b is B, which is more than 10 mm. The two cylindrical magnetron cathodes 14a, 14b (which may be made of titanium (Ti)) act as sputtering targets from which particles (e.g. titanium atoms) may be sputtered during the sputtering process for deposition on the substrate 12. Alternatively, one or both of the magnetron cathodes 14a, 14b may be in the shape of a rectangular prism.

An ion source unit 16 is spaced apart from the two spaced-apart cylindrical magnetron cathodes 14a, 14b by the same distance. In particular, the ion source unit 16 is in the form of a rectangular prism with a centre which lies on a line E which is perpendicular to and bisects the shortest line D joining the outer surface of the magnetron cathode 14a and the outer surface of the magnetron cathode 14b. The shortest distance between a front surface 18 of the ion source unit 16 and the line D is C. Put another way, the distance on the line E from the front surface 18 to the point where the line E intersects the line D is C. The relationship between C and A is that C<4 A. The front surface 18 of the ion source unit 16 has at least one outlet (not shown) allowing ionized particles (to be discussed below) to exit the ion source unit 16.

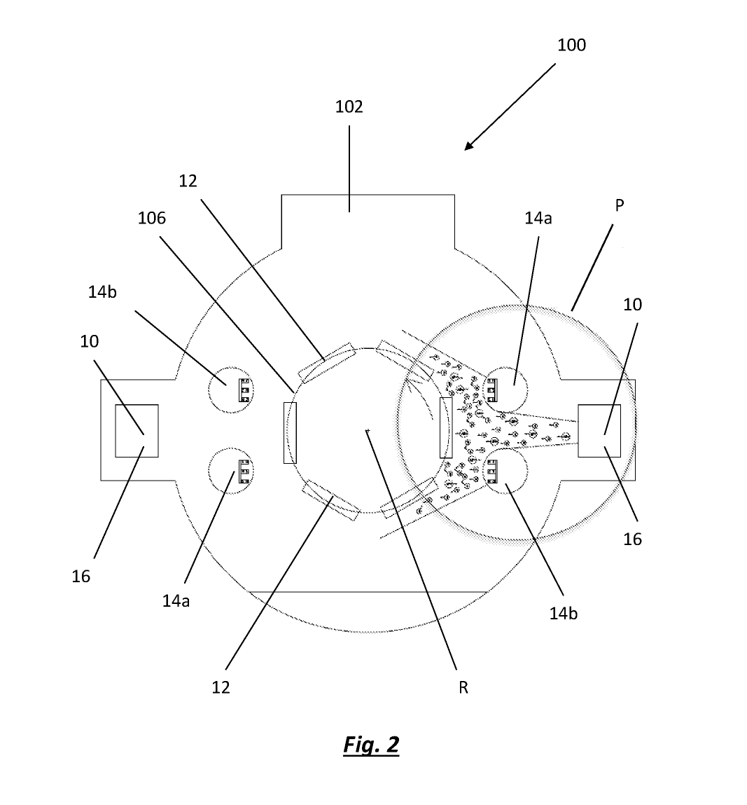

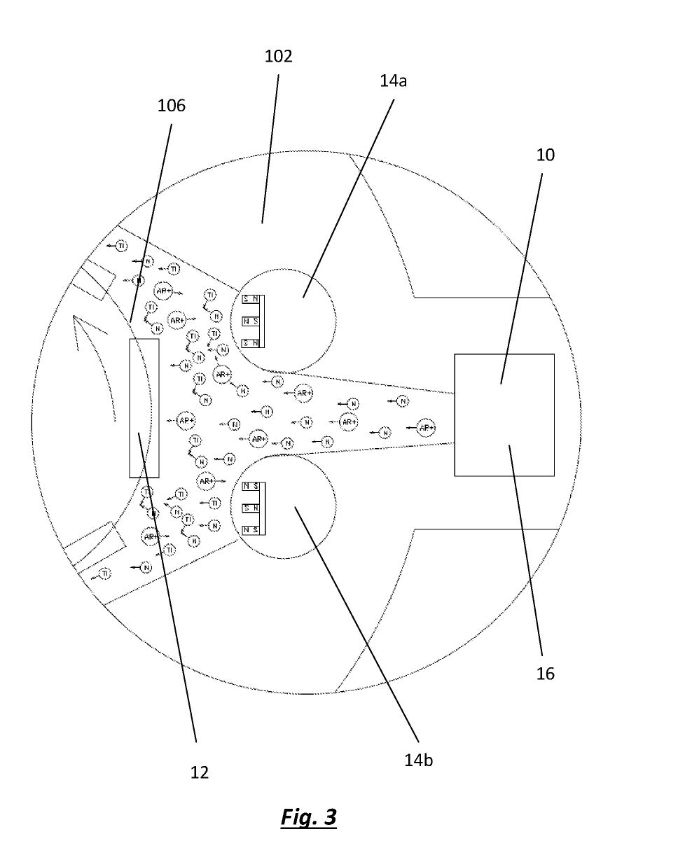

FIGS. 2 and 3 show a linear ion source assisted sputtering apparatus according to an embodiment of the present invention, generally designated as 100. The sputtering apparatus 100 includes a treatment chamber 102 (also called a “vacuum chamber”) in which a number of substrates 12 to be treated (e.g. to be coated) are placed. The substrates 12 are mounted on a support 106 which is rotatable relative to the chamber 102 about an axis of rotation R. In the sputtering apparatus 100, the support 106 (and thus the substrates 12 mounted thereon) are rotatable relative to the chamber 102 in an counter-clockwise direction, as indicated by the arrow in FIGS. 2 and 3. The sputtering apparatus 100 includes two linear ion source devices 10 as discussed above, each including an ion source unit 16 and two cylindrical magnetron cathodes 14a, 14b. In the sputtering apparatus 100, all the cylindrical magnetron cathodes 14a, 14b are titanium targets. As the ion source units 16 are fixedly installed in the sputtering apparatus 100, rotation of the substrates 12 relative to the chamber 102 also means rotation of the substrates 12 relative to the ion source units 16.

Generally speaking, to operate the sputtering apparatus 100, a number of substrates 12 to be treated are mounted on the support 106 and the pressure in the chamber 102 is reduced to a suitably low level. A suitable amount of argon (Ar) gas is introduced into the chamber 102. An electric voltage is applied to the magnetron cathodes 14a, 14b so as to form a continuous glow plasma field in front of the magnetron cathodes 14a, 14b, i.e. in a space between the magnetron cathodes 14a, 14b and the substrates 12. At the same time, the ion source units 16 are energized to ionize the gas supplied to the interior of the ion source units 16. The ionized (i.e. charged) gas particles are accelerated by the ion source units 16 to exit the ion source units 16 and travel in a straight line to pass through the space between the magnetron cathodes 14a, 14b, to subsequently reach the glow plasma field in front of the magnetron cathodes 14a, 14b. By way of such an arrangement, the density of the plasma in front of the magnetron cathodes 14a, 14b is increased, thus raising the ionization rate of the plasma field.

As a first working example, and using the sputtering apparatus 100 in this first working example, two ion source units 16 were installed diametrically opposite to each other within the sputtering apparatus 100 with the chamber 102 of a diameter of 800 mm. For each of the ion source units 16, the distance A was 155 mm, the distance B was 65 mm and the distance C was 200 mm. Each of the magnetron cathodes 14a, 14b was a self-rotating cylindrical titanium target, which was set at a working power of 5 kW, and the ion source units 16 were energized by an electric current of 2 A. Argon gas was supplied to the interior of each of the ion source units 16 at a rate of 100 sccm (“standard cubic centimeters per minute”, i.e. cm³/min), and nitrogen gas was supplied to the interior of each of the ion source units 16 at a rate of 20 sccm. By using such an arrangement, the substrates 12 were coated/deposited firstly with a layer of titanium (Ti) and then with a layer of titanium nitride (TiN). The time duration for coating/depositing the layer of titanium on the substrates 12 was 5 minutes and that for coating/depositing the layer of titanium nitride on the substrates 12 was 25 minutes.

As a control/reference example, under the same hardware and operating conditions as in the first working example discussed in the preceding paragraph, a number of substrates 12 were also treated/deposited in the sputtering apparatus 100, with the only exception being that no electric current was supplied to energize the ion source units 16.

After completion of the sputtering process, the substrates 12 treated according to the first working example were inspected by a Konica Minolta 3700A spectrophotometer, with the result of L: 72, a: 3.5, b: 32. Scanning electronic microscope (SEM) images of the substrates 12 thus treated showed that the coating was of a thickness of 1.2 μm. Similarly, the substrates 12 treated according to the control/reference example were also inspected by a Konica Minolta 3700A spectrophotometer, with the result of L: 65, a: 2.7, b: 22. Scanning electronic microscope (SEM) images of the control/reference substrates 12 showed that the coating was of a thickness of 0.9 μm.

TiN coating is gold in colour. The higher is the value of b, the closer the colour is to gold. L stands for lightness. The high values of L and b in the substrates 12 treated according to the first working example according to the present invention over and above those in the control/reference substrates 12 show that in the deposition process according to the first working example, the chemical reaction between titanium and nitrogen was more vigorous. The TiN coating formed by the sputtering method according to the present invention is of a brighter colour and the coating is also thicker. This means that the energy and density of the plasma have been increased, thus allowing for more sufficient chemical reaction for forming TiN, and increasing the deposition rate.

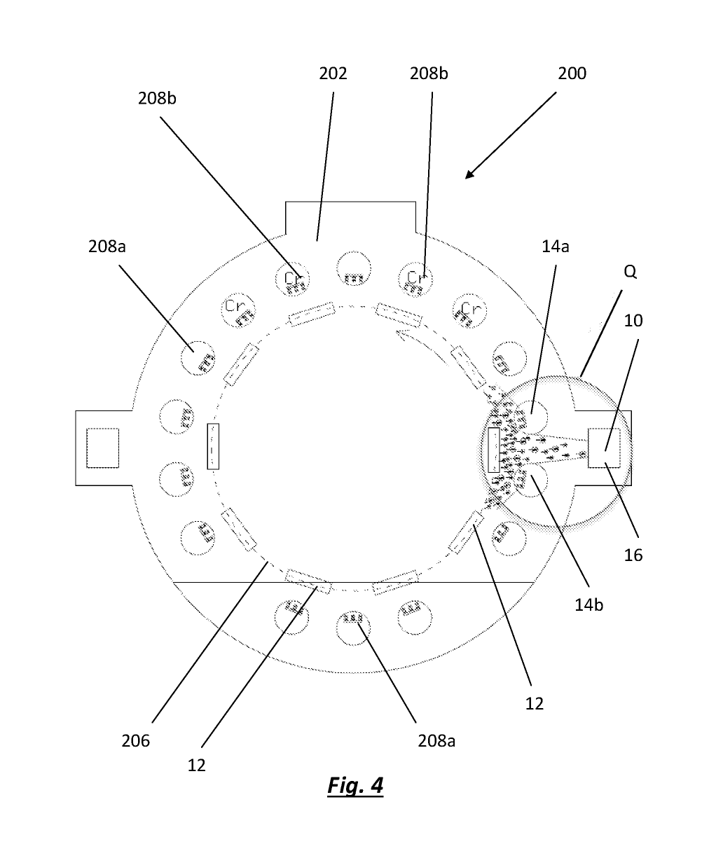

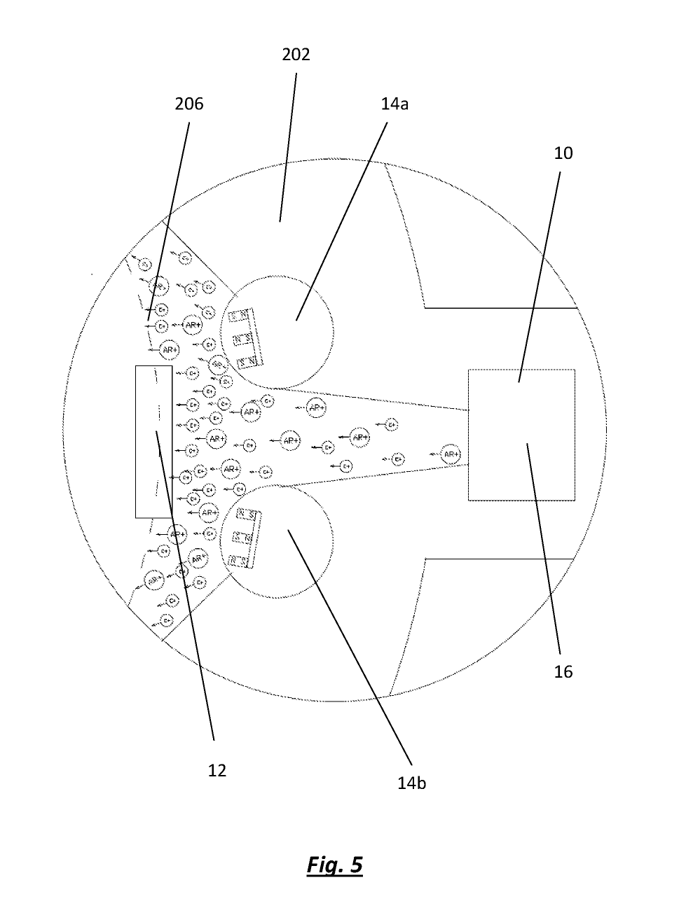

FIGS. 4 and 5 show a linear ion source assisted sputtering apparatus according to another embodiment of the present invention, generally designated as 200. The sputtering apparatus 200 includes a treatment chamber 202 (also called a “vacuum chamber”) in which a number of substrates 12 to be treated (e.g. to be coated) are placed. The substrates 12 are mounted on a support 206 which is rotatable relative to the chamber 202 about a central axis of rotation. In the sputtering apparatus 200, the support 206 (and thus the substrates 12 mounted thereon) are rotatable relative to the chamber 202 in a counter-clockwise direction, as indicated by the arrow in FIG. 4. The sputtering apparatus 200 includes one ion source device 10 as discussed above, including an ion source unit 16 and two cylindrical magnetron cathodes 14a, 14b. These two cylindrical magnetron cathodes 14a, 14b are titanium targets. As the ion source unit 16 is fixedly installed in the sputtering apparatus 200, rotation of the substrates 12 relative to the chamber 202 also means rotation of the substrates 12 relative to the ion source unit 16.

In the sputtering apparatus 200, in addition to the two cylindrical magnetron cathodes 14a, 14b, there are fourteen other cylindrical magnetron cathodes 208a, 208b, of which ten cylindrical magnetron cathodes 208a are made of titanium (Ti) (thus serving as titanium targets) and the other four cylindrical magnetron cathodes 208b are made of chromium (Cr) (thus serving as chromium targets). When in operation, the magnetron cathodes 14a, 14b, 208a, 208b) collectively form a circular un-balanced closed magnetic field.

As a second working example, and using the sputtering apparatus 200 in this second example, a diamond-like carbon (DLC) coating was deposited on substrates 12 mounted on the support 206 of the apparatus 200 for rotation relative to the ion source device 10. The pressure in the treatment/vacuum chamber 202 was reduced to below 8×10⁻³ Pa, and argon gas was supplied to the chamber 202 at a rate of 300 sccm. The four chromium sputtering targets 208b were activated and set at a power of 8 kW. The substrates 12 were biased at a voltage of −200 V. After deposition of chromium onto the substrates 12 for 20 minutes, the chromium sputtering targets 208b were deactivated. Argon gas was supplied to the interior of the ion source unit 16 of the ion source device 10 at a rate of 200 sccm and acetylene (C₂H₂) gas was supplied to the interior of the ion source unit 16 at a rate of 400 sccm. The ion source unit 16 was then activated and energized by an electric current of 2 A. The substrates 12 were biased at a voltage of −1,000 V and underwent a further deposition process for 150 minutes. The acetylene molecules were ionized to form ionized carbon atoms and ionized hydrogen atoms, which, because of the highly biased substrates 12 and the closed magnetic field, travelled fast in a straight line from the ion source unit 16, passed the space between the magnetron cathodes 14a, 14b, and reached the plasma field formed around the substrates 12. The highly energized carbon ions provided by the ion source unit 16 were deposited on the chromium coating to form a diamond-like carbon (DLC) coating.

After completion of the deposition process, the substrates 12 thus treated/coated in the second working example were tested by Raman spectroscopy, which showed that the percentage of sp³ bond in the DLC layer/coating was around 50%. Scanning electronic microscope (SEM) results showed that the thickness of the DLC layer/coating was around 2.0 μm, with a nano hardness of 22-28 GPa. The DLC coating is of good erosion resistance.

It should be understood that the above only illustrates examples whereby the present invention may be carried out, and that various modifications and/or alterations may be made thereto without departing from the spirit of the invention.

It should also be understood that certain features of the invention, which are, for clarity, described in the context of separate embodiments, may be provided in combination in a single embodiment. Conversely, various features of the invention which are, for brevity, described in the context of a single embodiment, may also be provided separately or in any appropriate sub-combinations.

1. An ion source device including:
at least a first magnetron cathode and a second magnetron cathode, each having a respective central longitudinal axis, and
an ion source unit with a surface facing generally said first magnetron cathode and said second magnetron cathode,
wherein said ion source unit is adapted to emit ions to pass through a space between said first magnetron cathode and said second magnetron cathode.

2. A device according to claim 1, wherein said central longitudinal axis of said first magnetron cathode and said central longitudinal axis of said second magnetron cathode are spaced apart from each other by a distance A, wherein a shortest line joining a surface of said first magnetron cathode and a surface of said second magnetron cathode is of a distance B, wherein a centre of said ion source unit lies on a line substantially perpendicular to and bisecting said shortest line, wherein a shortest distance between said surface of said ion source unit and said shortest line is C, and wherein B>10 mm and C<4 A.

3. A device according to claim 1, wherein at least one of said first magnetron cathode and said second magnetron cathode is in a shape of a cylinder or rectangular prism.

4. A device according to claim 1, wherein said ion source unit is in a shape of a rectangular prism.

5. A device according to claim 1, wherein at least one of said first magnetron cathode and said second magnetron cathode is a titanium target or a chromium target.

6. A device according to claim 1, wherein said ion source unit is adapted to emit argon ions, and nitrogen ions, carbon ions, or both.

7. A device according to claim 1, wherein said ion source unit is adapted to receive and ionize at least one gas, and to emit ions of said at least one gas.

8. A device according to claim 7, wherein said at least one gas is argon, nitrogen or acetylene.

9. A sputtering apparatus including at least one ion source device according to claim 1.

10. An apparatus according to claim 9, including a plurality of said ion source devices according to claim 1.

11. An apparatus according to claim 9, further including a support for releasably engaging with at least one substrate to be treated, wherein said support is rotatable about an axis of rotation.

12. An apparatus according to claim 9, wherein at least one of said first magnetron cathode and said second magnetron cathode is a titanium target, at least another one of said first magnetron cathode and said second magnetron cathode is a chromium target, or both.

13. A sputtering method, including:
(a) providing a treatment chamber with at least one ion source device according to claim 1,
(b) placing at least one substrate to be treated in said treatment chamber,
(c) applying an electric voltage to said first magnetron cathode and said second magnetron cathode to form a plasma field between said substrate and said first magnetron cathode and said second magnetron cathode,
(d) rotating said substrate relative to said ion source device,
(e) supplying at least one gas to said ion source unit, and
(f) energizing said ion source unit to ionize said at least one gas, to emit ions of said at least one gas, and to cause said ions of said at least one gas to pass through a space between said first magnetron cathode and said second magnetron cathode to reach said plasma field.

14. A method according to claim 13, wherein said plasma field is a glow plasma field.

15. A method according to claim 13, wherein at least one of said first magnetron cathode and said second magnetron cathode is a titanium target or a chromium target.

16. A method according to claim 13, wherein said at least one gas is argon, nitrogen or acetylene.

17. A method according to claim 13, wherein said emitted ions are argon ions and nitrogen ions, carbon ions, or both.

18. A method according to claim 13, wherein, in (f), said ion source unit is energized by an electric current of substantially 2 A.

19. A method according to claim 13, wherein, in (f), said ions of said at least one gas is accelerated by said ion source unit.
